(19) United States
(12) Patent Application Publication
(10) Pub. No.: US 2016/0005792 A1
(43) Pub. Date: Jan. 7, 2016

(54) SEMICONDUCTOR MEMORY DEVICE, AND METHOD FOR PRODUCING THE SAME

(71) Applicant: Renesas Electronics Corporation, Kanagawa (JP)

(72) Inventors: Makoto UEKI, Kanagawa (JP); Nobuyuki IKARASHI, Kanagawa (JP); Jun KAWAHARA, Kanagawa (JP); Kiyoshi TAKEUCHI, Kanagawa (JP); Takashi HASE, Kanagawa (JP)

(21) Appl. No.: 14/750,060

(22) Filed: Jun. 25, 2015

(30) Foreign Application Priority Data
Jul. 2, 2014 (JP) 2014-136529

(51) Int. Cl. H01L 27/24; H01L 45/00

(52) U.S. Cl. CPC H01L 27/2436; H01L 45/1633; H01L 45/145; H01L 45/1233; H01L 45/1253

(57) ABSTRACT

Provided is a semiconductor memory device (resistance random access memory element) improved in properties. A Ru film is formed as a film of a lower electrode by sputtering, and a Ta film is formed thereonto by sputtering. Next, the Ta film is oxidized with plasma to oxidize the Ta film. In this way, a compound Ta₂O₅ is produced and further Ru is diffused into the compound to form a layer (variable resistance layer) in which Ru is diffused into the compound Ta₂O₅. Such an incorporation of a metal (such as Ru) into a transition metal oxide TMO (such as Ta₂O₅) makes it possible to form electron conductive paths additional to filaments to lower the filaments in density and thickness. Thus, the memory element can be restrained from undergoing OFF-fixation, by which the element is not easily lowered in resistance, to be improved in ON-properties.

### CROSS-REFERENCE TO RELATED APPLICATIONS

The disclosure of Japanese Patent Application No. 2014-136529 filed on Jul. 2, 2014 including the specification, drawings and abstract is incorporated herein by reference in its entirety.

### BACKGROUND

The present invention relates to a semiconductor memory device, and a method for producing the semiconductor memory device, and is usable suitably for, for example, a resistance random access memory semiconductor device.

As one kind of nonvolatile memory element, a resistance random access memory (ReRAM) element is known. For example, Non-patent Literature listed below discloses a resistance random access memory element using Ta₂O₅. This literature discloses such an OFF-fixation defective that a memory element is higher in OFF resistance value than ordinary memory elements so that even when the memory element is caused to make an ON-operation, the memory element is not changed in resistance. In order to restrain the defective, disclosed is a technique that before an ordinary ON-pulse voltage is applied to such a memory element, a higher voltage pulse having a reverse polarity is applied thereto.

### CITATION LIST

### Non-Patent Literature

Non-patent Literature 1: A. Kawahara, et al., “Filament Scaling Forming Technique and Level-Verify-Write Scheme with Endurance Over 107 Cycles in ReRAM”, ISSCC Dig. Tech Papers, pp. 220-222, February 2013

The inventors have been engaging in researches and developments on resistance random access memory semiconductor devices as described above, and making eager investigations on an improvement thereof in properties. In a process of the investigations, it has proved that there is a room for making a further improvement in the structure of a resistance random access memory semiconductor device, and a method for producing the device.

Other objects and novel features of the present invention will be made clear from the description of the present specification and the attached drawings.

### SUMMARY

Each of two typical aspects of the invention disclosed in the present specification is briefly as follow:

A summary of a semiconductor memory device of one of the aspects includes a first electrode, a second electrode, and a variable resistance layer arranged between the first and second electrodes. This variable resistance layer includes an oxide layer of a first metal, and a second metal contained in the oxide layer of the first metal. The first metal is a transition metal, and the second metal is a metal that produces an electronic level inside a band gap of the oxide layer of the first metal.

A summary of a method of the other aspect for producing a semiconductor memory device includes the steps of forming, over a first electrode, a variable resistance layer having an oxide layer of a first metal and a second metal contained in the oxide layer of the first metal. The first metal is a transition metal, and the second metal is a metal that produces an electronic level inside a band gap of the oxide layer of the first metal.

According to the semiconductor memory device of the first aspect, properties thereof can be improved.

According to the method of the second aspect for producing a semiconductor memory device, a memory device good in properties can be produced.

### BRIEF DESCRIPTION OF THE DRAWINGS

FIG. 1 is a sectional view illustrating a structure of a semiconductor memory element used in a semiconductor memory device used in First Embodiment.

FIG. 2 is a sectional view illustrating a structure of a semiconductor memory element in Second Embodiment.

FIGS. 3A, 3B and 3C are each a chart showing an example of the concentration distribution of Ru in plane X-Y in FIG. 2.

FIG. 4 is a chart showing an example of the Ru concentration distribution in plane A-B in FIG. 2.

FIG. 5 is a sectional view illustrating a structure of a semiconductor memory element used in a semiconductor memory device used in Second Embodiment.

FIG. 6 is a sectional view illustrating a structure of a semiconductor memory element used in a semiconductor memory device used in Third Embodiment.

FIG. 7 is a sectional view illustrating a structure of a semiconductor memory device of Fourth Embodiment.

FIG. 8 is a section view illustrating a step in a process for producing the semiconductor memory device of Fourth Embodiment.

FIG. 9 is a section view illustrating a step in the process after the step illustrated in FIG. 8.

FIG. 10 is a section view illustrating a step in the process after the step illustrated in FIG. 9.

FIG. 11 is a section view illustrating a step in the process after the step illustrated in FIG. 10.

FIG. 12 is a section view illustrating a step in the process after the step illustrated in FIG. 11.

FIG. 13 is a section view illustrating a step in the process after the step illustrated in FIG. 12.

FIG. 14 is a section view illustrating a step in the process after the step illustrated in FIG. 13.

FIGS. 15A and 15B are each a TEM image showing a state that an upper electrode, a variable resistance layer and a lower electrode are laminated onto each other; and FIG. 15C is a graph showing secondary ion mass spectrometric analysis results of a case shown in each of FIGS. 15A and 15B.

FIG. 16 is a graph showing a relationship between a matter as to whether or not a TiO₂ film is present (in two memory elements), and the OFF-fixation incidence rate of each of the elements.

FIGS. 17A and 17B are each a graph showing a relationship between the matter as to whether or not the TiO₂ film is present (in the two memory elements) and the ON-state retention property of one of the elements.

FIGS. 18A and 18B are each a graph showing a plasma oxidization condition dependency of the resistance value of a variable resistance layer.

FIG. 19 is a sectional view of a structure of a semiconductor memory device of application 1 of Fifth Embodiment.

FIG. 20 is a sectional view of a structure of a semiconductor memory device of application 2 of Fifth Embodiment.

FIG. 21 is a sectional view of a structure of a semiconductor memory device of application 3 of Fifth Embodiment.

### DETAILED DESCRIPTION

In the present item, the present invention is described in the state of being divided into plural sections or embodiments as required for convenience. These are related to each other unless it is clearly stated that these are unrelated to each other. Thus, one of the sections or embodiments may have, for example, such a relation that the one is a varied example or an application example of another thereof, a detailed or supplement description about another thereof. In the case of referring to, in the item, the number of elements, the quantity or size of an element, any property of an element, or any other, the number or the like is not limited to any specified numerical value or range thereabout that is described in the item, for example, unless it is clearly stated that the number or the like is limited to a specified numerical value or range, or unless the number or the like is clearly limited to a specified numerical value or range in light of a principle or theory concerned therewith. Thus, the number or the like may be more than or less than the described numerical value or range.

In the item, any described constituent (or step) described is not essential for the present invention, for example, unless the claims recite the constituent or step, or unless the constituent or step is related to a scope equivalent theoretically to the scope of the invention according to the claims. Similarly, when in the item, the shape of any constituent, a positional relationship between constituents or any other conception is referred to, the shape or the like may be substantially similar or approximate one, as well as a numerical value or range as described above, for example, unless it is clearly stated that the shape or the like is limited to specified one, or unless the shape or the like is clearly limited to specified one in light of a principle concerned therewith.

Hereinafter, the embodiments will be described in detail with reference to the drawings. In all the drawings referred to for describing the embodiments, the same reference signs, or signs related to each other are attached, respectively, to members having the same function, and repeated description thereof is omitted. When plural similar members (moieties) are present, a sign obtained by attaching an additional sign to a generic sign may represent any individual or specified one of the members or the moieties. In the item, the same or similar members or moieties are not repeatedly described in principle except any case where a repeated description is especially necessary.

Even when some of the drawings referred to for describing the embodiments are each a sectional view, hatching thereinto may be omitted in order to make the view easy to view.

In any one of the sectional views, the size of any one of illustrated moieties does not correspond to that of an actual device drawn in the view, and any specific moiety of the moieties may be illustrated to be relatively enlarged.

### First Embodiment

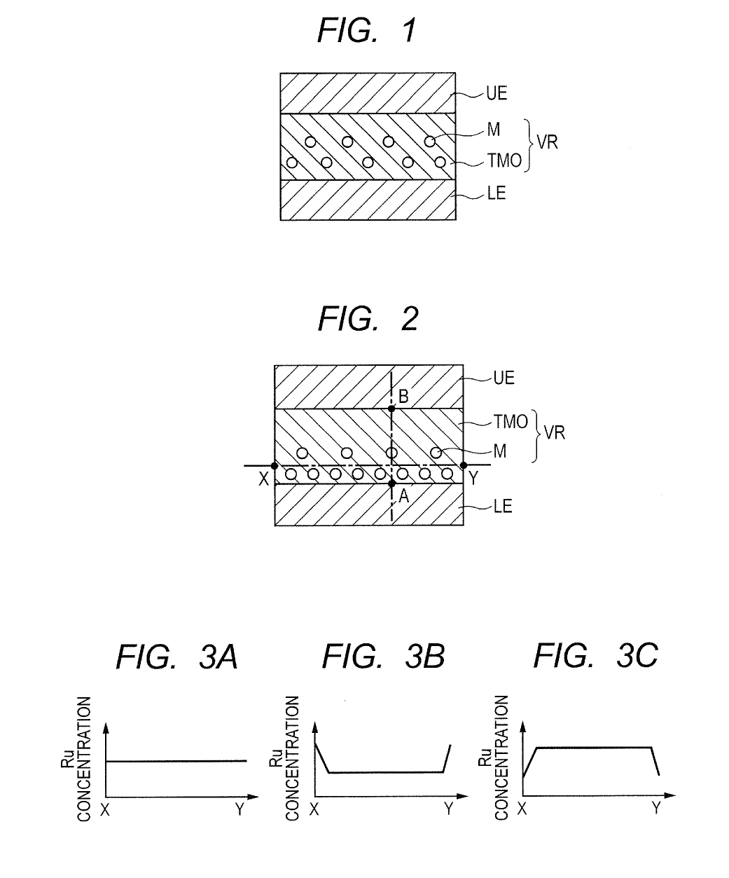

Hereinafter, with reference to some of the drawings, a detailed description will be made about a semiconductor memory device (memory device) of First Embodiment of the present invention. FIG. 1 is a sectional view illustrating a structure of a semiconductor memory element used in the semiconductor memory device of the present embodiment.

As illustrated in FIG. 1, the semiconductor memory element (resistance random access memory element) in the present embodiment has a lower electrode LE, a variable resistance layer VR, and an upper electrode UE. In this manner, the resistance random access memory element has a structure in which a transition metal oxide layer is sandwiched, from the upper and lower surfaces thereof, between electrode material layers, that is, an MIM structure of metal-insulator-metal layers.

In the resistance random access memory element, the resistance value of the variable resistance layer is variable by applying a voltage to between the electrodes. This memory element memorizes a data (0 or 1) in accordance with whether this resistance value is in a high resistance state (OFF-state) or in a low resistance state (ON-state). For example, the memory element regards the high resistance state (OFF-state) as “0” and the low resistance state (ON-state) as “1” to memorize data.

The resistance random access memory element requires an initializing processing called forming before the memory element is caused to make a switching operation. In the forming processing, a high voltage is applied to the resistance random access memory element to form conductive paths called filaments, in which oxygen deficit states are coupled to each other, in the metal oxide (insulator) film. After the forming processing, a voltage or current is applied to the memory element to vanish the conductive paths partially. In this way, the memory element is made into a high resistance state (ON-state). In short, the memory element memorizes “0”. When the memory element is caused to memorize “1” after the forming processing, it is sufficient for the conductive paths to be maintained to make the memory element into a low resistance state (ON-state). When the high resistance state (OFF-state), i.e., a data “0” is rewritten into a low resistance state (ON-state), i.e., a data “1”, conductive paths are again formed by the application of a voltage or current.

In this way, a data “0” or a data “1” can be memorized and rewritten into the resistance random access memory element.

In the resistance random access memory element in the present embodiment, the lower electrode LE is made of a conductive material, for example, Ru. The conductive material for forming the lower electrode LE may be formed by, for example, sputtering. The upper electrode UE is made of a conductive material, for example, W. The conductive material for forming the upper electrode UE may be formed by, for example, sputtering or chemical vapor deposition (CVD). As will be detailed later, the lower electrode LE is electrically coupled to a transistor for selection (see Fourth Embodiment).

The variable resistance layer VR contains a transition metal oxide TMO and a metal (different metal) M.

The transition metal is an element present from elements in the Group 3 to elements in the Group 11. The transition metal oxide TMO may be, for example, Ta₂O₅, ZrO, or HfO₂. The transition metal oxide TMO is desirably amorphous.

The metal M is contained in the transition metal oxide TMO. The metal M is a metal different from the metal that forms the transition metal oxide TMO, and is a metal that produces an electronic level inside a bad gap of the transition metal oxide TMO. The metal M is, for example, Ru, Re, Ir, Os or Nb.

Such an incorporation of the metal M into the transition metal oxide TMO makes it possible to restrain the memory element from undergoing OFF-fixation to improve the element in ON-properties. Examples of the ON-properties referred to herein include rewriting property from an OFF-state to an ON-state, ON-state maintaining property, and ON-state reading-out property.

In other words, the incorporation of the metal M into the transition metal oxide TMO makes it possible that electron conductive paths additional to the filaments are formed by effect of the metal M to improve the ON-properties.

About any conventional resistance random access memory element, in particular, in the case of rewriting data (ON- and OFF-operations) repeatedly, the filaments (oxygen deficit portions) are lowered in density and thickness so that the memory element is not easily lowered in resistance (OFF-fixation).

By contrast, in the present embodiment, the incorporation of the metal M into the transition metal oxide TMO makes it possible to compensate for a decline in the density and thickness of the filaments (oxygen deficit portions) by the additional electron conductive paths based on the metal M, so that the memory element can avoid OFF-fixation. In this way, the memory element can be improved in data-rewriting property and reading-out property.

The method for forming the variable resistance layer VR containing the transition metal oxide TMO and the metal M is not particularly limited. An example thereof will be described hereinafter. FIG. 2 is a sectional view illustrating a structure of a semiconductor memory element in the present embodiment.

For example, a metal M is diffused from a lower electrode LE to a film of a transition metal oxide TMO, so that a variable resistance layer VR containing the transition metal oxide TMO and the metal M can be formed.

Specifically, a Ru film is formed as a film of a lower electrode LE by, for example, sputtering, and a Ta film is formed thereonto by, for example, sputtering. Next, the Ta film is oxidized with plasma to oxidize the Ta film. In this way, Ta₂O₅ (transition metal oxide TMO), which has a chemically stoichiometric composition, is produced. Ta₂O₅ has an amorphous film structure. At the time of the plasma oxidization, Ru (metal M) diffuses into the Ta₂O₅ film. By varying conditions for the plasma oxidization, the quantity of Ru in the Ta₂O₅ film is controllable (see Fourth Embodiment).

As will be described later also, the Ru proportion (the Ru content by percentage) in the Ta₂O₅ film is from about 1 to 20% by atom of Ta₂O₅ (see Fourth Embodiment). If the Ru proportion is more than 20% by atom, steadily conductive paths, in which additional electron conductive paths based on Ru are coupled to each other, are formed so that the OFF-operation of the memory element is not easily made. Conversely, if the Ru proportion is less than 1% by atom, the memory element cannot sufficiently avoid OFF-fixation.

The variable resistance layer VR may be formed by co-sputtering the transition metal oxide TMO and the metal M. However, according to the step of diffusing the metal M from the lower electrode LE into the transition metal oxide TMO, the transition metal oxide TMO film and the variable resistance layer VR can be formed in a short time. Moreover, the variable resistance layer VR can easily be formed to have a preferred Ru concentration distribution that will be detailed below.

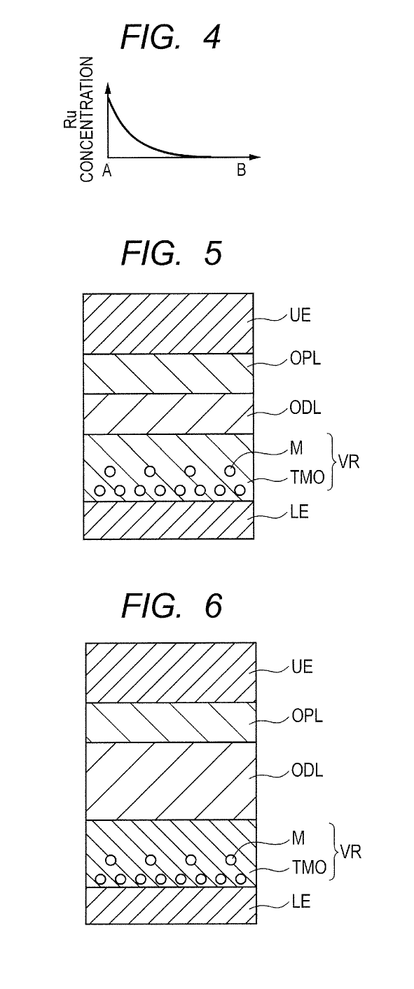

The following will describe the concentration distribution of the metal M in the variable resistance layer VR. FIGS. 3A to 3C are each a chart showing an example of the concentration distribution of Ru in plane X-Y in FIG. 2. In the case of observing the Ru concentration in the Ta₂O₅ film in a plane parallel to the upper and lower electrodes, it is desired that as illustrated in FIG. 3A, the Ru concentration is even (concentration difference: less than 20%). As illustrated in FIG. 3B or 3C, when the concentration distribution is uneven, the memory element is varied or dispersed in properties. From the viewpoint of a restraint of the varied properties, it is desired that the resistance random access memory layer VR has an even concentration distribution as illustrated in FIG. 3A. When the metal M is diffused from the lower electrode LE, the Ru concentration in the layer VR has a distribution of a higher concentration at a side of the Ta₂O₅ layer (layer VR) that is nearer to the Ru film, as illustrated in FIG. 4. FIG. 4 is a chart showing an example of the Ru concentration distribution in plane A-B in FIG. 2. According to FIG. 4, the Ru concentration becomes higher at the side of the layer VR that is nearer to the Ru film, and the Ru concentration becomes smaller nearer to the upper electrode UE. The switching operation of the memory element would be caused by the cut or growth of filaments in the vicinity of the Ru film; by heightening the metal M concentration at the side of the layer VR that is nearer to the electrode related to the switching operation, the memory element can be effectively restrained from undergoing OFF-fixation and be stabilized in ON-properties. However, when Ru is distributed evenly with a high concentration (for example, a concentration more than 20% by atom) in plane A-B, initial leakage is increased so that a filament formation failure may be unfavorably caused. When Ru is distributed evenly with a low concentration (for example, a concentration less than 1% by atom) in plane A-B, the OFF-fixation may not be sufficiently restrained. It is preferred to produce such a concentration distribution that Ru is located at a higher concentration at positions of the layer VR that are nearer to the Ru film (lower electrode LE) related to the switching while the Ru concentration is lowered at positions of the layer VR that are nearer to the upper electron UE.

### Second Embodiment

First Embodiment (FIG. 2) has been made into a structure in which from the lower side thereof the lower electrode (such as a Ru film) LE, the variable resistance layer (such as a Ta₂O₅ film) VR, and the upper electrode (such as a W film) UE are arranged. However, an oxygen withdrawing layer may be laid between the variable resistance layer VR and the upper electrode UE. Moreover, an antioxidative layer may be laid on the oxygen withdrawing layer.

FIG. 5 is a sectional view illustrating a structure of a semiconductor memory element used in a semiconductor memory device of Second Embodiment. The resistance random access memory element in the present embodiment has a structure in which from the lower side thereof a lower electrode LE, a variable resistance layer VR, an oxygen withdrawing layer ODL, an antioxidative layer OPL, and an upper electrode UE are successively arranged.

The lower electrode LE, the variable resistance layer VR and the upper electrode UE may be formed in the same manner as in the First Embodiment, using the same material as therein.

Specifically, the lower electrode LE is made of a conductive material, for example, Ru. The conductive material of the lower electrode LE can be formed into a film by, for example, sputtering. The upper electrode UE is made of a conductive material, for example, W. The conductive material of the upper electrode UE can be formed into a film by, for example, sputtering or CVD. As will be described later also, the lower electrode LE is electrically coupled to a transistor for selection (see Fourth Embodiment).

The variable resistance layer VR contains a transition metal oxide TMO, and a metal M.

The transition metal is an element present from elements in the Group 3 to elements in the Group 11. The transition metal oxide TMO may be, for example, Ta₂O₅, ZrO, or HfO₂. The transition metal oxide TMO is desirably amorphous.

The metal M is contained in the transition metal oxide TMO. The metal M is a metal different from the metal that forms the transition metal oxide TMO, and is a metal that produces an electronic level inside a bad gap of the transition metal oxide TMO. The metal M is, for example, Ru, Re, Ir, Os or Nb.

The variable resistance layer VR can be formed, for example, by producing a transition metal onto the lower electrode LE and oxidizing this transition metal with plasma to form the transition metal oxide TMO, and further diffusing the metal M in the lower electrode LE into the transition metal oxide TMO.

Specifically, for example, a Ru film is formed as the lower electrode LE by, for example, sputtering, and a Ta film is formed thereonto by, for example, sputtering. Next, the Ta film is oxidized with plasma to oxidize the Ta film. In this way, Ta₂O₅, which has a chemically stoichiometric composition, is produced, and further Ru is diffused into the resultant Ta₂O₅ film. The thus formed Ta₂O₅ film in which Ru is diffused has an amorphous film structure.

The oxygen withdrawing layer ODL is formed onto the variable resistance layer VR. The oxygen withdrawing layer ODL is a film made of a conductive material (a metal in this case), for example, a Ta film. The oxygen withdrawing layer ODL may be a film made mainly of a metal other than Ta, such as Ti, Zr or Hf (metal content by percentage: for example, 50% or more). The conductive material of the oxygen withdrawing layer ODL can be formed into a film by, for example, sputtering.

The antioxidative layer OPL is formed onto the oxygen withdrawing layer ODL. The antioxidative layer OPL is made of a conductive material, and is, for example, a TaN film. The conductive material of the antioxidative layer OPL can be formed into a film by, for example, sputtering. The antioxidative layer OPL may be a metal compound film other than the TaN film, such as a TiN film, or a WN film. It is preferred to form the oxygen withdrawing layer ODL and the antioxidative layer OPL continuously in the state that a vacuum state is maintained without bringing these layers into contact with the outside air. After the formation of the oxygen withdrawing layer ODL and the antioxidative layer OPL, the workpiece is annealed. By this annealing, oxygen in the variable resistance layer VR is withdrawn so that oxygen deficits are introduced into the variable resistance layer VR. As a result, in the upper surface (upper electrode side surface) of the variable resistance layer (such as a Ta₂O₅ film) VR, a layer lower in oxygen concentration (for example, a TaOx film) is formed. The lower surface (lower electrode side surface) of the oxygen withdrawing layer ODL is oxidized so that a metal oxide is formed in a partial region of the layer. The annealing may be performed, using a thermal hysteresis in subsequent steps (such as an interconnection forming step (see Fourth Embodiment)) of this production process.

By the laying of the oxygen withdrawing layer ODL, the layer lower in oxygen concentration (for example, a TaOx film) is formed. Additionally, the laying of the oxygen withdrawing layer ODL makes it possible to heighten the oxygen-withdrawing effect. When an undesired oxide film is formed onto the front surface of the oxygen withdrawing layer ODL, this oxide film produces a parasite resistance to lower the resultant element in properties; however, the laying of the oxygen withdrawing layer ODL makes it possible to decrease the parasite resistance to stabilize the element properties. In this way, oxygen in the variable resistance layer VR is withdrawn and the oxygen deficits are introduced into the variable resistance layer VR, so that the forming voltage can be decreased.

The introduction of the oxygen deficits and the decrease in the forming voltage would make the formed filaments low in density and thin. As a result, the resultant memory element is not easily turned on so that the element is prejudiced into an OFF-state. As has been described in First Embodiment, therefore, additional electron conductive paths are formed by the metal M, whereby the memory element can be improved in ON-properties.

In the present embodiment, the oxygen withdrawing layer ODL, the antioxidative layer OPL and the upper electrode UE have been described as layers separated from each other. However, the oxygen withdrawing layer ODL and the antioxidative layer OPL have electroconductivity; thus, the two layers ODL and OPL may be regarded as a part of the upper electrode.

### Third Embodiment

In Second Embodiment (FIG. 5), as examples of the oxygen withdrawing layer ODL, metal films such as a Ta film have been given. However, the oxygen withdrawing layer ODL may be a film smaller in oxygen proportion than any transition metal film having a chemically stoichiometric composition.

FIG. 6 is a sectional view illustrating a structure of a semiconductor memory element used in a semiconductor memory device of Third Embodiment. The resistance random access memory element in the present embodiment has a structure in which from the lower side thereof a lower electrode LE, a variable resistance layer VR, an oxygen withdrawing layer ODL, an antioxidative layer OPL, and an upper electrode UE are successively arranged.

The lower electrode LE, the variable resistance layer VR and the upper electrode UE may be formed in the same manner as in the Second Embodiment, using the same material as therein.

The oxygen withdrawing layer ODL is formed onto the variable resistance layer VR. The oxygen withdrawing layer ODL is a layer of a transition metal oxide smaller in oxygen proportion than a transition metal oxide having a chemically stoichiometric composition. In the case of using, for example, an oxide of Ta for the oxygen withdrawing layer ODL, the oxygen withdrawing layer ODL is a TaOx film wherein x<2.5, which is smaller in oxygen proportion than a Ta₂O₅ film, which has a chemically stoichiometric composition. For the oxygen withdrawing layer ODL, the following may be used besides the Ta oxide: for example, an oxide of Ti, Zr, or Hf that is smaller in oxygen proportion than an oxide thereof that has a chemically stoichiometric composition. The oxygen withdrawing layer ODL can be formed by, for example, sputtering. The oxygen withdrawing layer (for example, a TaOx film wherein x<2.5) may be formed by depositing a transition metal (for example, Ta) by sputtering, and then subjecting the workpiece to oxidizing treatment. The oxidizing treatment may be a treatment such as plasma oxidization, radical oxidization, or thermal oxidization.

The antioxidative layer OPL is formed onto the oxygen withdrawing layer ODL. The antioxidative layer OPL is made of a conductive material, and is, for example, a TaN film. The conductive material of the antioxidative layer OPL can be formed into a film by, for example, sputtering. The antioxidative layer OPL may be besides the TaN film, for example, a TiN film or a WN film. It is preferred to form the oxygen withdrawing layer ODL and the antioxidative layer OPL continuously in the state that a vacuum state is maintained without bringing these layers into contact with the outside air. After the formation of the oxygen withdrawing layer ODL and the antioxidative layer OPL, the workpiece is annealed. By this annealing, oxygen in the variable resistance layer VR is withdrawn so that oxygen deficits are introduced into the variable resistance layer VR. As a result, in the upper surface (the upper electrode side surface) of the variable resistance layer (such as a Ta₂O₅ film) VR, a layer lower in oxygen concentration (for example, a TaOy film) is formed. The annealing may be performed, using a thermal hysteresis in subsequent steps (such as an interconnection forming step (see Fourth Embodiment)) of this production process.

By the laying of the oxygen withdrawing layer ODL, the layer lower in oxygen concentration (for example, a TaOy film) is formed. The laying of the antioxidative layer OPL makes it possible to heighten the oxygen-withdrawing effect through the oxygen withdrawing layer ODL. When an undesired oxide film is formed onto the front surface of the oxygen withdrawing layer ODL, this oxide film produces as a parasite resistance to lower the resultant element in properties; however, the laying of the antioxidative layer OPL makes it possible to decrease the parasite resistance to stabilize the element properties. In this way, the withdrawal of oxygen in the variable resistance layer VR and the introduction of the oxygen deficits are attained, so that the forming voltage can be decreased.

The introduction of the oxygen deficits and the decrease in the forming voltage would make the formed filaments low in density and thin. As a result, the resultant memory element is not easily turned on so that the element is prejudiced into an OFF-state. As has been described in First Embodiment, therefore, additional electron conductive paths are formed by the metal M, whereby the memory element is improved in ON-properties.

In the present embodiment, the oxygen withdrawing layer ODL, the antioxidative layer OPL and the upper electrode UE have been described as layers separated from each other. However, the oxygen withdrawing layer ODL and the antioxidative layer OPL have electroconductivity; thus, the two layers ODL and OPL may be regarded as a part of the upper electrode.

### Fourth Embodiment

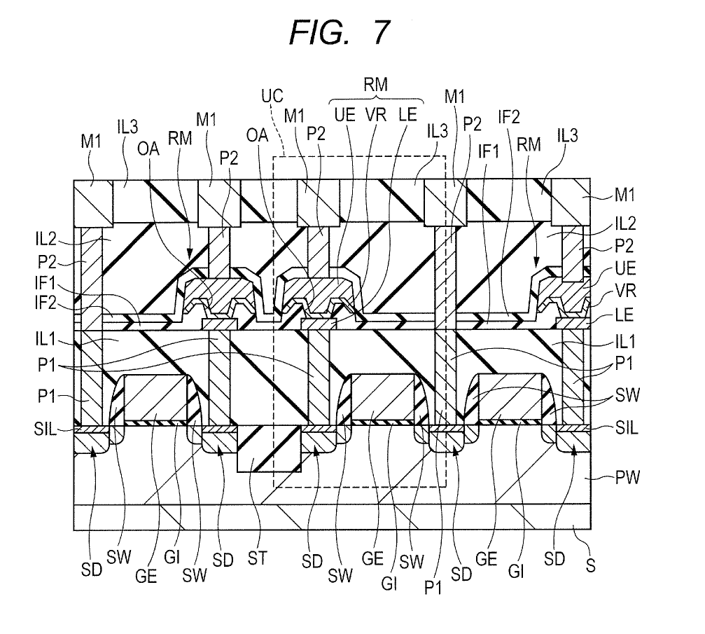

Hereinafter, with reference to some of the drawings, a semiconductor device of Fourth Embodiment will be described in detail. FIG. 7 is a sectional view illustrating a structure of a semiconductor memory device of the present embodiment.

The semiconductor memory device illustrated in FIG. 7 has transistors for selection, and resistance random access memory elements (resistance random access memory elements) RM. A lower electrode LE of each of the resistance random access memory elements RM is electrically coupled to one out of two source/drain regions SD of the corresponding transistor for selection (metal insulator semiconductor field effect transistor (MISFET) for switching). For example, the other source/drain region SD of the transistor for selection is coupled to a bit line (M1). For example, a gate electrode GE of the transistor for selection functions as a word line.

The resistance random access memory elements RM are arranged at respective intersections of bit lines including the bit line and word lines including the word line M1 to form a memory cell array.

[Description of Structure]

### <Transistors for Selection>

As illustrated in FIG. 7, each of the transistors for selection is formed in a main surface of a substrate (p-type well PW) made of a semiconductor, and at a region divided by an element isolation region ST. The transistor for selection has a gate electrode GE over the substrate (p-type well PW) S to interpose a gate insulator film GI therebetween, and source/drain regions SD located in the substrate (p-type well PW) S and at both sides of the gate electrode GE. A side wall SW is arranged on any side wall of the gate electrode GE. Thus, the source/drain regions each have the so-called LDD (lightly doped drain) structure.

Each of the transistors for selection is coupled to the corresponding resistance random access memory element RM through a plug P1. The plug P1 is arranged in an interlayer dielectric IL1. Specifically, one of the source/drain regions of the transistor for selection is coupled through a plug P1 to the lower electrode LE of the resistance random access memory element RM. The other source/drain region SD of the transistor for selection is coupled through the plug P1 and others to an interconnection (for example, the bit line M1). The transistor for selection and the resistance random access memory element RM form a unit cell UC. For example, any adjacent cells of the entire unit cells UC are arranged symmetrically to each other about the corresponding element isolation region ST or plug P1 coupled to the corresponding interconnection (for example, the bit line M1).

### <Resistance Random Access Memory Elements>

As illustrated in FIG. 7, each of the resistance random access memory elements has one of the lower electrodes LE, a variable resistance layer VR and an upper electrode UE. The lower electrode LE is made of a conductive material, such as Ru. The upper electrode UE is made of a conductive material, such as W.

The variable resistance layer VR is made of a transition metal oxide TMO and a metal M. In other words, this layer VR has a structure in which the metal M is dispersed in the transition metal oxide TMO.

The transition metal is an element present between elements in the Group 3 and elements in the Group 11. The transition metal oxide TMO may be, for example, Ta₂O₅, ZrO₂, or HfO₂.

The metal M is contained in the transition metal oxide TMO. The metal M is a metal different from the metal that forms the transition metal oxide TMO, and is a metal that produces an electronic level inside a bad gap of the transition metal oxide TMO. The metal M is, for example, Ru, Re, Ir, Os or Nb.

As has been detailed in the First Embodiment and others, such an incorporation of the metal M into the transition metal oxide TMO makes it possible to restrain the memory elements from undergoing OFF-fixation to improve the elements in ON-properties.

In the resistance random access memory elements RM in the present embodiment, the insulator film IF1 having openings OA is formed between the lower electrodes LE and the variable resistance layer VR (see FIG. 9). Each of the lower electrodes LE, and the variable resistance layer VR contact each other in the corresponding one of the openings OA. A region where this opening OA is made functions as a variable resistance region of the corresponding resistance random access memory element RM. The region where the opening OA is made is smaller than each of a region where the lower electrode LE is formed and a region where the variable resistance layer VR is formed, and is further smaller than a region where the upper electrode UE is formed.

When the variable resistance region of each of the resistance random access memory elements RM is specified by the corresponding opening OA in this way to avoid any edge region of the corresponding section of the variable resistance layer VR, the edge portion being a portion damaged and further easily changed in Ru concentration at the time of the etching, the memory element can be decreased in dispersion or variation of ON-properties and other element properties.

[Description of Production Method]

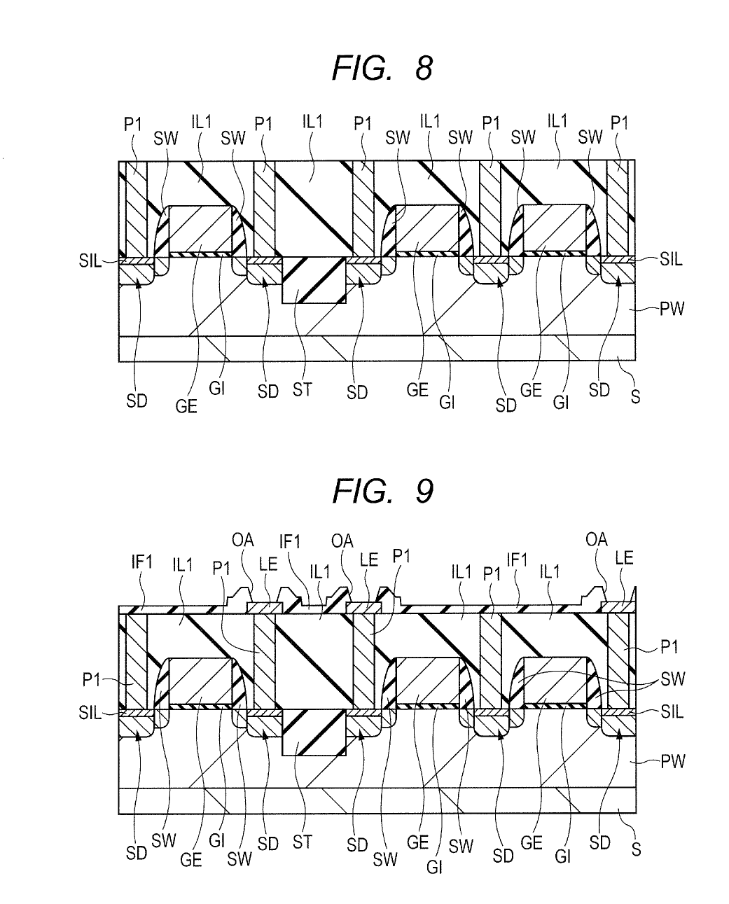

With reference to FIGS. 8 to 14, the following will describe a method for producing a semiconductor memory device of the present embodiment, and further make the structure of the semiconductor memory device clearer. FIGS. 8 to 14 are each a sectional view illustrating a step in a process for producing the semiconductor memory device of the embodiment.

As illustrated in FIG. 8, transistors for selection are initially formed in the vicinity of a main surface of a substrate S including a semiconductor (semiconductor substrate), and further an interlayer dielectric IL1 is formed thereon. The method for forming these members is not particularly limited. Specifically, these members can be formed, for example, through steps described below.

A substrate S is initially prepared. The substrate S may be, a substrate including, for example, p-type monocrystal silicon having a specific resistivity of, for example, about 1 to 10 Ωcm.

Next, a memory element isolation region ST is formed into the main surface of the substrate S. This memory element isolation region ST can be formed by, for example, a shallow trench isolation (STI) method. In this case, the memory element isolation region of the substrate S is initially etched to make a trench. Next, an insulator film, such as a silicon oxide film, is embedded into the trench. Specifically, for example, an insulator film, such as a silicon oxide film, is deposited onto the substrate including the inside of the trench, and then portions of the insulator film that are positioned in others than the trench are removed by, for example, chemical mechanical polishing (CMP) method. In this way, the insulator film is embedded into the trench.

By this memory element isolation region ST, divided active regions are produced, and transistors for selection, and other semiconductor memory elements are formed. Herein, a description will be made about an example in which the transistors for selections are n-channel type MISFETs. However, p-channel type MISFETs, the conductive type of which is reverse to the above-mentioned conductive-type, may be formed, as semiconductor memory elements for a peripheral circuit for driving a memory cell array, in a region where the peripheral circuit is to be formed. Moreover, both of n-channel type MISFETs and p-channel type MISFETs may be formed therein.

Next, a p-type well PW is formed in the active regions of the substrate S. The p-type well PW is formed, for example, by ion-implanting a p-type impurity into the substrate S. In this way, the p-type well PW, which is a p-type semiconductor region, can be formed from the main surface of the substrate S to a predetermined depth.

Next, gate electrodes GE are formed over the main surface of the substrate (p-type well PW) S to interpose a gate insulator film GI therebetween. Specifically, a gate electrode film GI, which is an insulator film, is initially formed on the main surface of the substrate S. This gate insulator film GI, which is, for example, a silicon oxide film, is formed by, for example, a thermal oxidization method. Next, for example, CVD is used to deposit a gate electrode material, such as polycrystal silicon, onto the gate insulator film GI. The resultant polycrystal silicon film is then patterned into a desired pattern to form gate electrodes GE. Patterning is a method of using a photolithographic technique to form a photoresist film having a desired shape onto a film such as a polycrystal silicon film, and then using a mask as this photoresist film to etch the film, such as the silicon film, thereby working this film into a desired shape.

Next, source/drain regions SD are formed in the substrate S and on both sides of each of the gate electrodes GE. Specifically, the workpiece is subjected to ion implantation, using the gate electrodes GE as a mask (ion-implantation blocking mask) to form an n⁻-type semiconductor region low in impurity concentration. Next, an insulator film which is, for example, a silicon oxide film is formed onto the substrate S including the gate electrodes GE. The resultant workpiece is anisotropically etched to form a side wall film SW on respective side walls of the gate electrodes GE. Next, the workpiece is subjected to ion implantation using the gate electrodes GE and the side wall film SW to form an n⁺-type impurity region high in impurity concentration. In this way, source/drain regions SD can be formed which each have an LDD structure having the n⁻-type semiconductor region low in impurity concentration and the n⁺-type semiconductor region higher in impurity concentration than the former region and large in junction depth.

Next, the workpiece is subjected to annealing treatment (thermal treatment) to activate the impurities introduced before this time.

Through these steps, transistors for selections can be formed in the vicinity of the main surface of the substrate S.

Next, a silicide technique is used to form a metal silicide film SIL on the n⁺-type semiconductor regions. Specifically, for example, a mask film covering the gate electrodes GE on the substrate S is formed, and then a cobalt (Co) film (not illustrated) is formed as a metal film on the substrate S by, for example, sputtering. Next, the workpiece is subjected to annealing treatment to cause silicon constituting the n⁺-type semiconductor regions (SD) to react with the Co film. In this way, a metal silicide SIL is formed on the n⁺-type semiconductor regions (SD). Next, unreacted fractions of the Co film are removed.

Next, an interlayer dielectric IL1 is formed on the substrate S. Specifically, for example, an insulator film such as a silicon oxide film is formed onto the substrate S by, for example, CVD. Thereafter, as required, the front surface of the insulator film is flattened by, for example, a CMP method.

Next, plugs (connecting portions) P1 are formed in the interlayer dielectric ILL Specifically, the interlayer dielectric IL1 on the source/drain regions SD are initially etched to made contact holes. A conductive film is embedded into the holes to form plugs (connecting portions) P1. Specifically, for example, a laminated film of a barrier conductor film (not illustrated) and a main conductor film (such as a W film) is formed on the interlayer dielectric IL1 including the contact holes, and then unnecessary portions of the laminated film that are positioned on the interlayer dielectric IL1 are removed by, for example, a CMP method or etching-back method.

Next, resistance random access memory elements RM are formed on the plugs P1, respectively. Specifically, the respective front surfaces of the plugs P1 and the interlayer dielectric IL1 are initially etched by Ar plasma. In this way, an oxide film on the front surface of each of the plugs P1 can be removed, so that the state of contact between the plugs P1 and the resistance random access memory elements RM can be made good.

Next, as illustrated in FIG. 9, lower electrodes LE are formed on the plugs P1, respectively. Specifically, for example, a conductive film is deposited onto the plugs P1 and the interlayer dielectric IL1 by, for example, sputtering. In this case, as the conductive film, a laminated film of a Ru film and a Ta film is deposited. Specifically, a Ta film is initially deposited onto the plugs P1 by sputtering, and a Ru film is deposited onto the Ta film by sputtering. At this time, it is preferred to deposit the Ru film continuously in the state that a vacuum state is kept without bringing the Ta film into contact with the outside air. The Ta film in the laminated film functions as an adhesive layer. In other words, the Ta film is interposed between the Ru film and the plugs P1 to improve the adhesiveness between the lower electrodes LE and the plugs P1. Additionally, the Ru film in the laminated film functions as a main metal (main electrode layer) constituting the lower electrodes LE, and further functions as a layer for introducing a metal M into a transition metal oxide TMO which will be detailed later (source for the diffusion of the metal M). In this case, the conductive layer has been formed by sputtering; however, this film may be formed by CVD. Next, the conductive film (Ru film/Ta film) is patterned to form lower electrodes LE. At the time of the patterning, an insulator film, such as a silicon oxide film, worked through a photoresist film may be used as a mask (referred to also as a hard mask) to etch the conductive film (Ru film/Ta film) positioned underneath the mask.

Next, an insulator film IF1 is formed which has openings OA above the lower electrodes LE, respectively. Specifically, for example, CVD is used to deposit a silicon nitride film as an insulator film IF1 onto the lower electrodes LE, the plugs P1 and the interlayer dielectric ILL The insulator film IF1 may be, besides the silicon nitride film, for example, a silicon oxynitride film, a silicon oxide, or a silicon carbonitride film (SiCN film).

Next, the insulator film (silicon nitride film) IF1 is patterned to make openings OA (referred to also as memory holes) above the lower electrodes LE, respectively. The region where each of the openings OA is made is positioned above one of the lower electrodes LE, and is smaller than the region where the lower electrode LE is formed. By the opening OA, an active region for resistance change is defined. In other words, the region where the opening OA is made is to be a variable resistance region for one of the resistance random access memory elements RM.

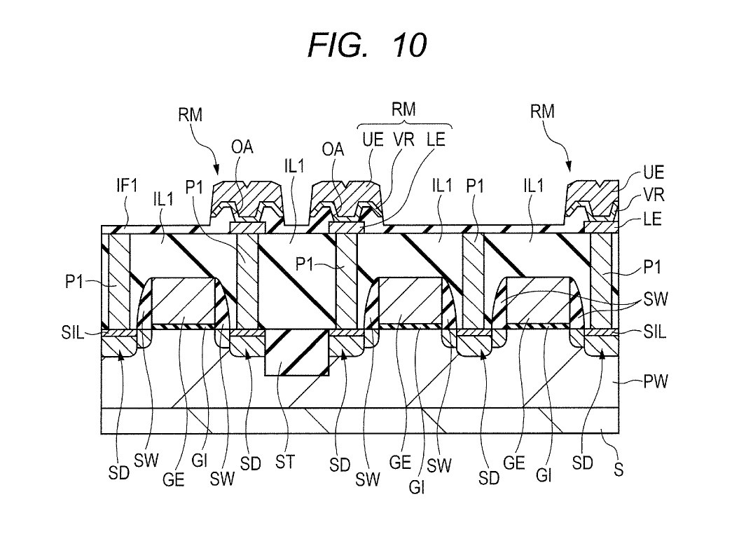

Next, as illustrated in FIG. 10, a variable resistance layer VR is formed on the openings OA. Specifically, for example, a Ta film is deposited onto the insulator film IF1 including the inside of the openings OA by sputtering. Next, the workpiece is subjected to plasma oxidizing treatment. Specifically, for example, a high-frequency power of 800 W is applied to the inside of a chamber having a pressure of 8.25 Torr (1 Torr=1 mmHg=133.322 Pa) to conduct this treatment for 300 seconds while N₂O is introduced into the chamber at a flow rate of 1000 sccm.

In this way, the Ta film is oxidized with plasma to make it possible to produce Ta₂O₅. Through this oxidizing process, Ru diffuses into the compound Ta₂O₅. In other words, a variable resistance layer VR can be formed which is a layer in which Ru diffuses into the compound Ta₂O₅.

The diffusion quantity of Ru (i.e., the proportion of Ru quantity in the variable resistance layer VR) is controllable by adjusting conditions for the plasma treatment. For example, as the plasma power or the treatment temperature is increased, the diffusion quantity of Ru can be increased, as will be described later also. However, as has been described in the First Embodiment, if the Ru quantity is too large, steadily electrically-conductive paths to which additional electron conductive paths based on Ru are coupled are formed so that the resultant memory elements do not easily make OFF operation. If the Ru quantity is too small, the memory elements can sufficiently avoid OFF-fixation. It is therefore preferred to adjust the Ru quantity into the range of about 1 to 20% by atom of Ta in Ta₂O₅.

Next, upper electrodes UE are formed on individual sections of the variable resistance layer VR, respectively. In the present embodiment, an oxygen withdrawing layer, an antioxidative layer and a main electrode layer are represented as each of the upper electrodes UE. Specifically, for example, a Ta film is deposited as an oxygen withdrawing film onto the variable resistance layer VR by sputtering. This oxygen withdrawing layer (Ta film) withdraws oxygen from the variable resistance layer (Ta₂O₅) VR positioned underneath the oxygen withdrawing layer, so that oxygen deficit portions are generated in an upper portion of the variable resistance layer (Ta₂O₅) VR. In other words, a layer low in oxygen concentration (TaOx, x<2.5) is formed in an upper portion of the variable resistance layer (Ta₂O₅) VR. As a result, near the boundary between the oxygen withdrawing layer (Ta film) and the variable resistance layer (Ta₂O₅), a concentration gradient of oxygen is generated. For example, the oxygen concentration in the variable resistance layer (transition metal oxide) VR is the highest and stoichiometrically stable on the side of this layer that contacts the lower electrodes LE coupled to the transistors for selection. At a farther portion of the variable resistance layer VR from the lower electrodes LE toward the upper electrodes UE, the portion is made lower in oxygen concentration.

Next, a TaN film is deposited as an antioxidative layer onto the oxygen withdrawing layer by sputtering. At this time, it is preferred to use, for example, a multi-chamber apparatus to form the TaN film as the antioxidative layer continuously in the state that a vacuum state is kept without bringing the Ta film, which is the oxygen withdrawing layer, into contact with the outside air. This antioxidative layer (TaN film) can prevent a natural oxidation of the front surface of the oxygen withdrawing layer (Ta film). This manner makes an improvement in an effect that the oxygen withdrawing layer (Ta film) withdraws oxygen from the variable resistance layer (Ta₂O₅) VR positioned underneath the oxygen withdrawing layer. This manner also makes it possible to decrease a parasitic resistance based on the naturally oxidized film to stabilize memory element properties of the resultant.

Next, an upper electrode UE layer is formed on the antioxidative layer. Specifically, for example, a conductive film is deposited onto the antioxidative layer (TaN film). In this case, the conductive film is a W film obtained by depositing W by sputtering or CVD.

Next, the upper electrode UE laminated layer (the oxygen withdrawing layer, the antioxidative layer and the main electrode layer) and the variable resistance layer VR are patterned to form resistance random access memory elements RM. In this way, the upper electrode UE laminated layer and the variable resistance layer VR are worked at a time. The region where each of the upper electrodes UE is formed and the region where one section of the patterned variable resistance layer VR (that is positioned underneath the upper electrode UE) is formed each include the region where one of the openings OA is made, and are each larger than the opening OA. When the variable resistance region of each of the resistance random access memory elements RM is specified by the corresponding opening OA in this way, the variable resistance region is specified to avoid any edge region of the corresponding variable resistance layer VR section, the edge portion being a portion damaged and further easily changed in Ru concentration at the time of the etching. Thus, the resultant individual resistance random access memory elements can be decreased in dispersion or variation of ON-properties and other element properties.

Specifically, there is a high possibility that in the edge region of each section of the patterned variable resistance layer VR, the Ru concentration is made different from that of the inside of the section by, for example, the atmosphere of plasma at the etching time, or the peeling of the film used as any one of the masks (such as the photoresist film or the hard mask). For example, if the upper electrode UE laminated layer (the oxygen withdrawing layer, the antioxidative layer and the main electrode layer), the variable resistance layer VR, and the lower electrode LE layer are successively laminated and then the resultant is worked at a time, any edge region of each section of the patterned variable resistance layer VR is also turned to a variable resistance region. If the variable resistance region is specified to include such an edge region, which is an edge region of each section of the patterned variable resistance layer VR, the Ru concentration in the edge region becomes instable so that the resultant semiconductor memory devices may unfavorably become large in property dispersion, as has been described in the First Embodiment.

By contrast, when the lower electrodes LE are each formed and subsequently the corresponding variable resistance layer VR section and upper electrode UE are formed over the low electrode LE to interpose, therebetween, the insulator film IF1 having the openings OA, the internal region of the variable resistance layer VR section, in which the Ru concentration is more evenly changed, functions as a variable resistance region so that the resultant memory elements are improved in stability of ON properties and other element properties.

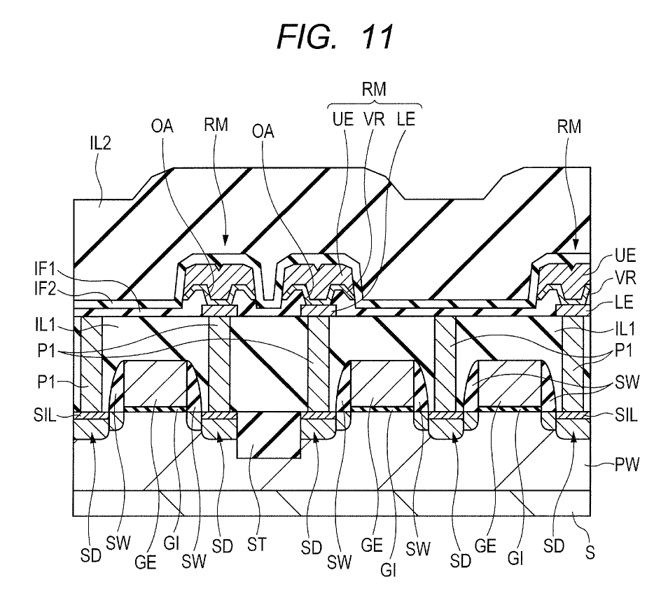

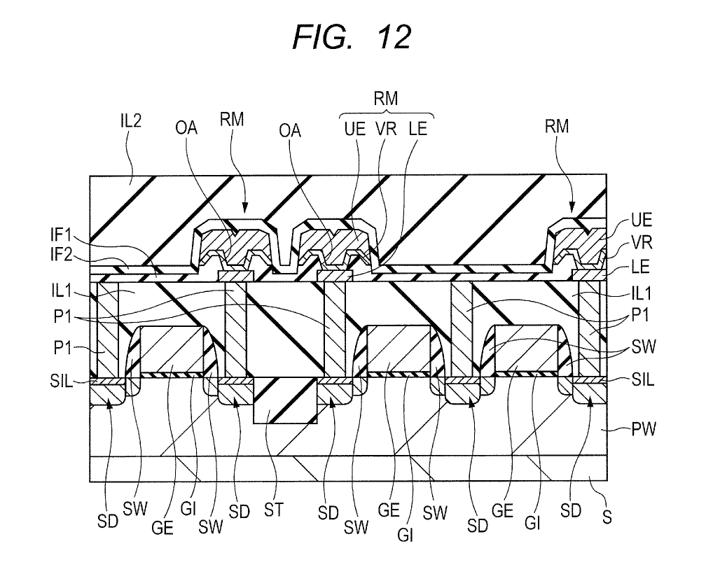

Thereafter, as illustrated in FIG. 11, an insulator film (covering insulator film) IF2 and an interlayer dielectric IL2 are successively deposited on the insulator film IF1 and the variable resistance layer VR. Specifically, for example, a silicon nitride film is deposited as an insulator film (covering insulator film) IF2 onto the insulator film IF1 and the upper electrodes UE, using, for example, CVD. The insulator film IF2 may be, besides the silicon nitride film, for example, a silicon oxynitride film, a silicon oxide, or a silicon carbonitride film (SiCN film). Next, a silicon oxide film is deposited as an interlayer dielectric IL2 onto the insulator film IF2, using, for example, CVD. The interlayer dielectric IL2 may be, besides the silicon oxide film, for example, a silicon carbonitride film (SiCN film). Next, for example, a CMP method is used to remove the upper of the interlayer dielectric IL2 to flatten the front surface of the interlayer dielectric IL2 (FIG. 12).

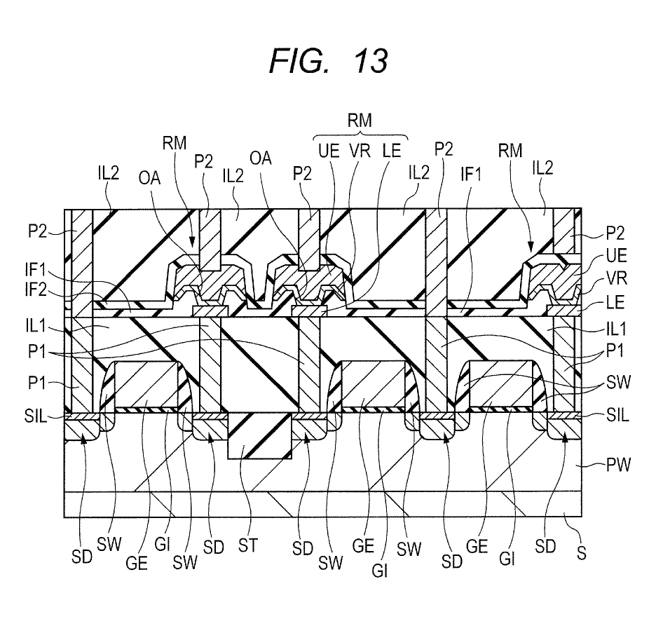

Next, as illustrated in FIG. 13, plugs P2 are formed in the interlayer dielectric IL2 and the insulator films IF1 and IF2. Specifically, contact holes are initially made by etching the interlayer dielectric IL2, and the insulator films IF1 and IF2 over the plugs P1 and the upper electrodes UE. A conductive film is embedded into the holes to form plugs P2. Specifically, for example, a laminated film of a barrier conductor film (not illustrated) and a main conductor film (for example, a W film) is formed onto the interlayer dielectric IL2 including the inside of the contact holes. Unnecessary portions of the film that are positioned on the interlayer dielectric IL2 are removed by, for example, a CMP method or etching-back method.

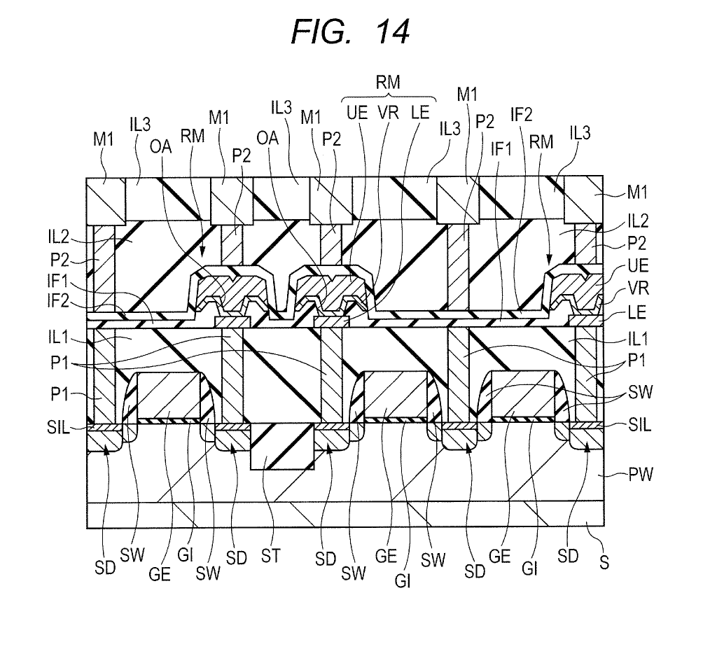

Next, as illustrated in FIG. 14, an interconnection M1 is formed on the interlayer dielectric IL2, in which the plugs P2 are embedded. The interconnection M1 is formed, using, for example, a damascene technique (a single damascene technique in this case). Specifically, an insulator film IL3 for making trenches is formed on the interlayer dielectric IL2, and then interconnection trenches are made in this trench-making insulator film IL3. Thereafter, a conductive film is embedded into the interconnection trenches to form an interconnection M1. The conductive film for forming the interconnection M1 may be a film made mainly of a metal such as W, Al or Cu.

Thereafter, an interlayer dielectric, plugs and a trench-making insulator film may be formed on the interconnection M1 to form a multilayered interconnection. When the interconnection is formed, a dual damascene method may be used. In other words, a conductive film is embedded into the contact holes and the interconnection trenches, at the same time, which are made in the interlayer dielectric and in the trench-making insulator film, respectively. In this way, plugs and an interconnection are formed to be integrated with each other. In this case, the interconnection is made by the damascene method. However, the interconnection M1 and any interconnection above the interconnection M1 may be formed by patterning. For example, it is allowable to deposit a conductive film onto the interlayer dielectric IL1 in which the plugs P2 are embedded, and then pattern the resultant to form the interconnection M1.

As described above, in the same manner as in the First Embodiment and others, the present embodiment also makes it possible to diffuse the metal M into the transition metal oxide TMO to restrain each of the resultant semiconductor memory elements from undergoing any OFF-fixation and improve the memory element in ON-properties.

Examples: the following will describe the inventors' examples for verification.

### <Verification 1>

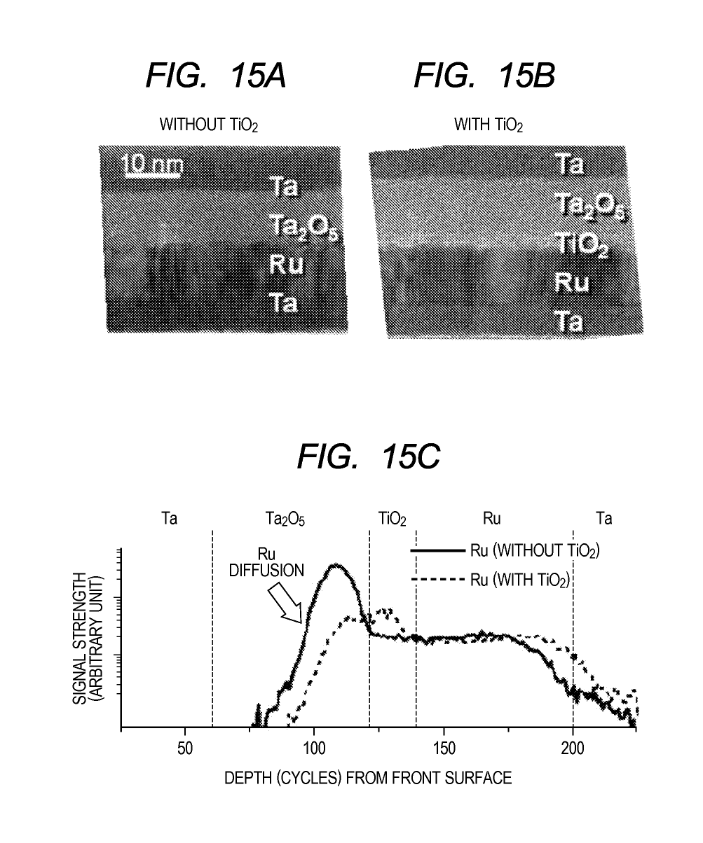

FIG. 15A and FIG. 15B are each a transmission electron microscope (TEM) image showing the state that an upper electrode, a variable resistance layer and a lower electrode are laminated onto each other. Specifically, FIG. 15A shows a state that from the lower layer side of the laminate, a Ta film, a Ru film, a Ta₂O₅ film, and a Ta film are successively laminated. FIG. 15B shows a state that from the lower layer side of the laminate, a Ta film, a Ru film, a TiO₂ film, a Ta₂O₅ film, and a Ta film are successively laminated. A difference between the respective laminates in FIG. 15A and FIG. 15B is whether the TiO₂ film is present between the Ta₂O₅ film and the Ru film (FIG. 15B), or not (FIG. 15A). FIG. 15C shows respective secondary ion mass spectrometric analysis (SIMS analysis) results of the case in FIG. 15A and that in FIG. 15B. Its vertical axis represents the signal strength (arbitrary unit) of each of these laminated elements. Its horizontal axis represents the depth (cycles) from the front surface of the laminated elements.

Hereinafter, these examples will be described in detail.

In the case illustrated in FIG. 15A, that is, the example without any TiO₂ film, a Ta film was formed on a Ru film by sputtering, and then a He/N₂O gas was used to oxidize the workpiece with plasma at 350° C. and 800 W for 5 minutes to form a Ta₂O₅ film. A Ta film (oxygen withdrawing layer) was then formed onto the Ta₂O₅ film by sputtering.

In the case illustrated in FIG. 15B, that is, the example with the TiO₂ film, a Ti film was formed onto a Ru film by sputtering, and then a He/N₂O gas was used to oxidize the workpiece with plasma at 350° C. and 300 W for 10 minutes to forma TiO₂ film. Furthermore, a Ta film was formed onto the TiO₂ film by sputtering, and then a He/N₂O gas was used to oxidize the workpiece with plasma at 350° C. and 800 W for 5 minutes to form a Ta₂O₅ film. A Ta film (oxygen withdrawing layer) was then formed onto the Ta₂O₅ film by sputtering.

As shown in FIG. 15C, in each of the structure without any TiO₂ film (that corresponds to a solid line) and that with the TiO₂ film (that corresponds to a broken line), it was verified that a signal according to Ru was generated in the Ta₂O₅ film at a side thereof nearer to the Ru film. This matter demonstrates that Ru was diffused into the Ta₂O₅ film in each of the two cases. In the case of the solid line without any TiO₂ film, a signal having a strength about 10 times larger than that in the case of the broken line with the TiO₂ film was detected.

This matter demonstrates that in the structure with the TiO₂ film, the diffusion of Ru into the Ta₂O₅ film is restrained by the TiO₂ film, and in the structure without any TiO₂ film, Ru diffuses in a larger quantity into the Ta₂O₅ film.

However, about the results of the case (solid line) without any TiO₂ film, the signal strength of Ru is larger in the Ta₂O₅ film than in the Ru film. This is affected by a matrix effect based on a difference in ionization rate and sputtering yield between the individual films to be analyzed, and does not demonstrate a difference between the Ru concentration in the Ru film and that in the Ta₂O₅ film. In such a way, from any graph obtained by secondary ion mass spectrometry, a comparison cannot be made between the respective element-concentrations in different film species.

In the structure without any TiO₂ film, a diffusion equation of Ru in the Ta₂O₅ film is determined from the diffusion concentration distribution of Ru into the Ta₂O₅ film, and then the atomic density of Ru in the Ta₂O₅ film is gained. As a result, in the case of regarding the Ru atomic density as one in the interface between the Ru film and the Ta₂O₅ film, the density at a depth of 2 nm from the interface is estimated to be about ⅕. The density at a depth of 5 nm therefrom is estimated to be about 1/100. In this way, Ru having a higher concentration is detected at a side of the Ta₂O₅ film that is nearer to the Ru film.

Considering the effect of the roughness of the interface, an actual quantity of Ru would be slightly smaller. The range of concentrations of Ru which can be expected to produce an advantageous effect would be from 1 to 20% by atom in the Ta₂O₅ film. The diffusion quantity of Ru can be controlled by conditions for the plasma oxidization when the Ta₂O₅ film is formed.

### <Verification 2>

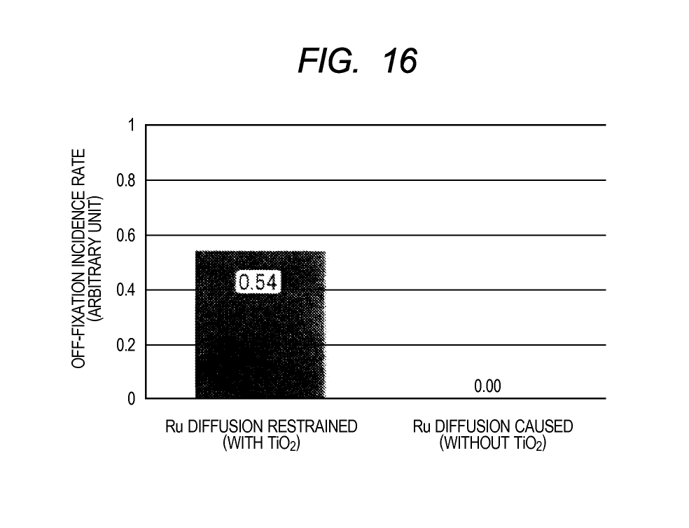

FIG. 16 is a graph showing a relationship between a matter as to whether or not the TiO₂ film is present (in the above-mentioned two memory elements), and the OFF-fixation incidence rate of each of the examples. About each of the above-mentioned structure without any TiO₂ film, and that with the TiO₂ film, the ON/OFF operation was made over 1000 cycles to examine the OFF-fixation incidence rate of the structure. The OFF-fixation incidence rate (of any memory element) is defined as such a defective proportion that at the time of ON-operation of the memory element, the memory element shows a high resistance of 1 MΩ or more. A vertical axis in FIG. 16 represents the OFF-fixation incidence rate (arbitrary unit).

As illustrated in FIG. 16, in the case with the TiO₂ film, that is, the case where the diffusion of Ru was restrained, the OFF-fixation incidence rate was 0.5. However, in the case without any TiO₂ film, that is, the case where the diffusion of Ru was generated, the OFF-fixation incidence rate was 0. It is understood that in the structure without any TiO₂ film, the OFF-fixation is restrained by the diffusion of Ru, as described herein.

### <Verification 3>

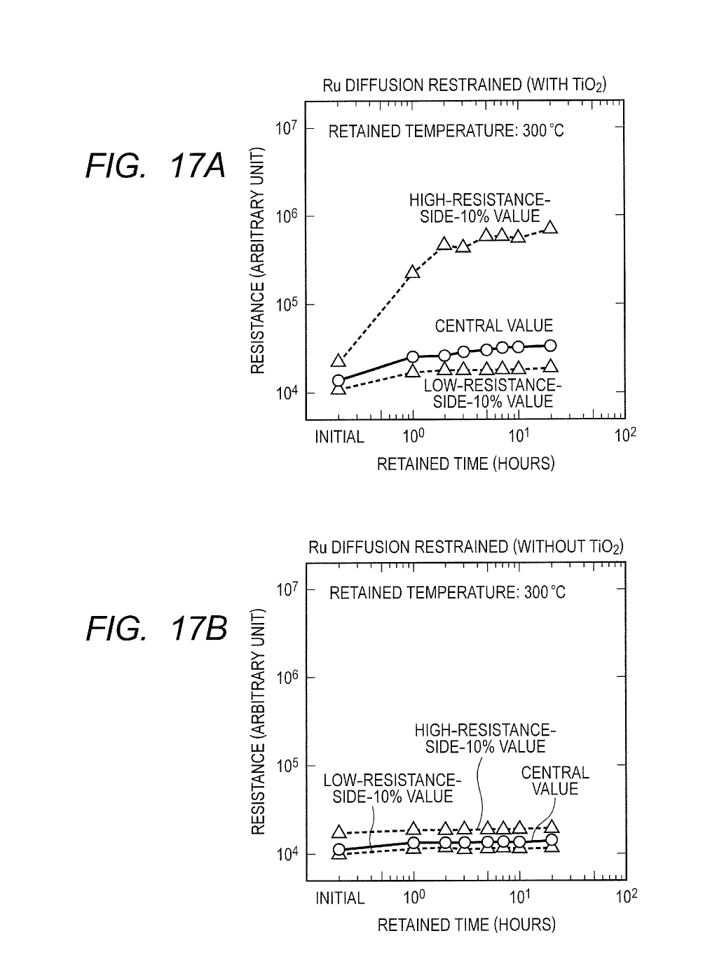

FIGS. 17A and 17B are each a graph showing a relationship between a matter as to whether or not the TiO₂ film is present (in the two memory elements) and the ON-state retention property of one of the memory elements. About each of the above-mentioned structure without any TiO₂ film, and that with the TiO₂ film, an examination was made about the ON-state retention property thereof at a high temperature. Specifically, when the structure (or the memory element) was retained at a temperature of 300° C., each of the memory elements was examined about a fluctuation in the resistance thereof about each of memory operations of 1024 bits, the fluctuation being relative to the retained time (hours). FIG. 17A shows the structure with the TiO₂ film; and FIG. 17B, that without any TiO₂ film. Their vertical axis represents the resistance (arbitrary unit), and their horizontal axis represents the retained time (hours). A central value (in each of these figures) is the value of a data positioned at the center when respective resistance value data about the 1024 bits are arranged in the order of the magnitude of the values. A high-resistance-side-10% value is the value of a data positioned 10% apart from the highest resistance when the resistance value data about the 1024 bits are arranged in the order of the magnitude of the values. A low-resistance-side-10% value is the value of a data positioned 10% apart from the lowest resistance when the resistance value data about the 1024 bits are arranged in the order of the magnitude of the values.

As illustrated in FIG. 17A, in the case with the TiO₂ film, that is, the case in which the diffusion of Ru is restrained, bits plotted at the 10% or more high-resistance side from the central value are recognized at a larger portion. As the retained time becomes longer, the resistance value rises. By contrast, as illustrated in FIG. 17B, in the case without any TiO₂ film, that is, the case in which the diffusion of Ru is generated, a rise the resistance value is not recognized, and thus it is understood that the resistance fluctuation is restrained. As described herein, it is understood that in the case without any TiO₂ film, that is, the case in which the diffusion of Ru is generated, the retention property of the ON state is excellent.

### <Verification 4>

The diffusion quantity of Ru is controllable in accordance with conditions for the plasma oxidization. In other words, as described above, a Ta film is formed onto a Ru film, and then the Ta film is oxidized with plasma to form a Ta₂O₅ film, which has a chemically stoichiometric composition; at this time, in accordance with conditions for the plasma oxidization, the Ru diffusion quantity is controllable.

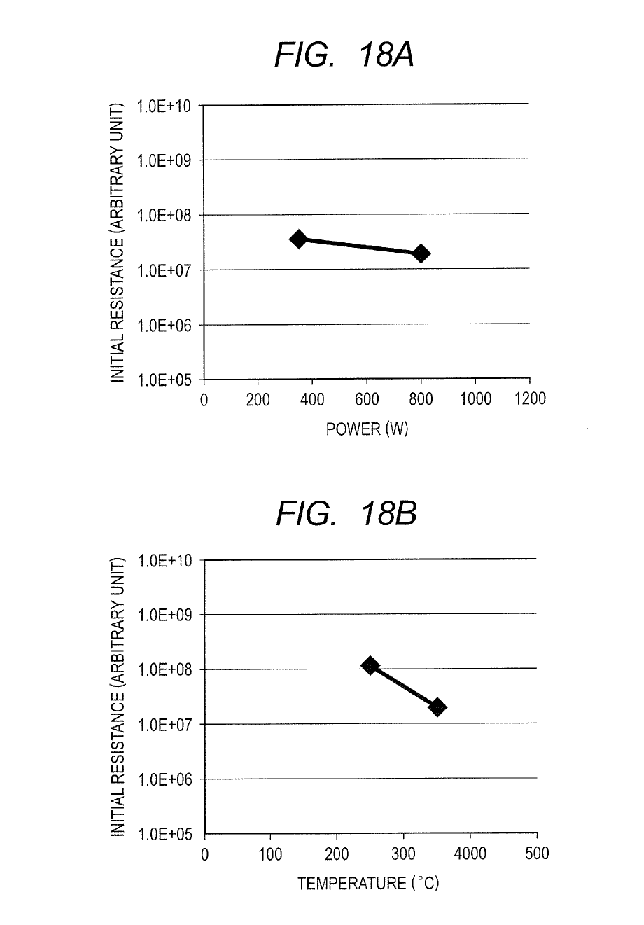

About such a structure, FIGS. 18A and 18B are each a graph showing a plasma oxidization condition dependency of the resistance value of its variable resistance layer. FIG. 18A shows the dependency of plasma power out of the plasma oxidization conditions, and FIG. 18B shows the dependency of plasma-oxidizing temperature out of the same conditions. In FIG. 18A, its vertical axis represents the initial resistance (arbitrary unit) of the layer, and its horizontal axis the power (W) of the plasma. In FIG. 18B, its vertical axis represents the initial resistance (arbitrary unit), and its horizontal axis the plasma-oxidizing temperature (° C.). The initial resistance is the resistance value between electrodes of the resistance random access memory element before the element is subjected to forming treatment. About FIG. 18A, the temperature is 350° C.; and about FIG. 18B, the power is 800 W.

When a large quantity of Ru is diffused in the Ta₂O₅ film on the Ru film, many additional conductive paths are formed so that the initial resistance is lowered. As shown in FIG. 18A, as the plasma power is higher, the initial resistance is lower. As shown in FIG. 18B, as the temperature for the plasma treatment is higher, the initial resistance is lower. Thus, it can be concluded that the Ru diffusion quantity is controllable in accordance with the plasma oxidization conditions (such as the power or the temperature).

According to a comparison between FIGS. 18A and 18B, the resistance fluctuation by the temperature change is larger than that by the power change. It is understood that as described herein, the memory element is relatively high in sensitivity to the temperature. Thus, in order to diffuse Ru effectively in accordance with the plasma oxidization conditions, the plasma oxidization is conducted in a temperature range preferably from 250 to 400° C., more preferably from 300 to 350° C. Such a temperature range is relatively easily set. This manner makes it easier to cope with the control of the Ru diffusion quantity than the manner of raising the plasma power. Thus, for example, even at a relatively low power (of, for example, 300 to 500 W), Ru can be effectively diffused by conducting the plasma oxidizing treatment at a temperature range preferably from 250 to 400° C., more preferably from 300 to 350° C. In the present specification, the plasma oxidization denotes that an oxidizing gas (such as oxygen, ozone or nitrous oxide) is excited with a high-frequency discharge to be converted into plasma, and the plasma is used to oxidize a matter to be treated (a film to be oxidized in the present case) set in a reaction processing chamber; the power (plasma power) denotes a power for exciting the reaction gas, for example, a power applied to discharge electrodes inside the reaction processing chamber; and the (plasma-oxidizing) temperature denotes the temperature of the inside of the reaction processing chamber.

### Fifth Embodiment

In Fifth Embodiment, a description will be made about application examples of the semiconductor memory device.

### Application Example 1

In the Fourth Embodiment (FIG. 7), each of the plugs P1 has been directly coupled to the corresponding lower electrode LE, and the plug P1 has been directly coupled to the corresponding plug 2. However, an interconnection may be laid between the plug P1, and the lower electrode LE and/or the plug P2.

[Description of Structure]

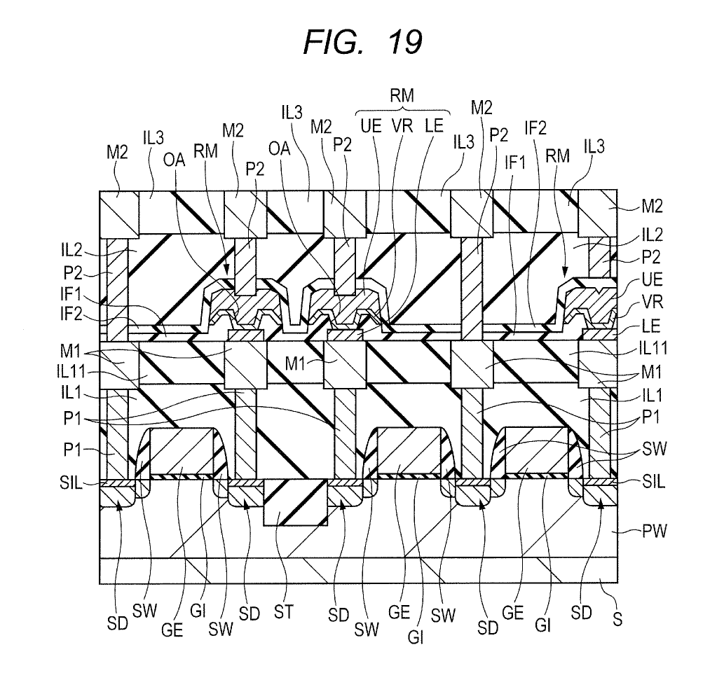

FIG. 19 is a section view illustrating a structure of a semiconductor memory device of application example 1 of the present embodiment.

Transistors for selection each have the same structure as in the Fourth Embodiment. Specifically, each transistor for selection is located in a main surface of a substrate (p-type well PW) S and over a region divided by an element isolation region ST. The transistor has a gate electrode GE formed over the substrate S to interpose a gate insulator film GI therebetween, and source/drain regions SD located in the substrate (p-type well PW) S and at both sides of the gate electrode GE. The source/drain regions SD each have an LDD structure. Two plugs P1 are arranged, respectively, over the source-drain regions SD of the transistor for selection. One of the plugs P1 is coupled through an interconnection M1 to a lower electrode LE of a resistance random access memory element RM. The other plug P1 is coupled through the interconnection M1 to a plug P2. The interconnection M1 is embedded in a trench-making insulator film IL11.

The resistance random access memory element RM on the interconnection M1 has the same structure as in the Fourth Embodiment. Specifically, the resistance random access memory element RM has the lower electrode LE, a variable resistance layer VR and an upper electrode UE. The lower electrode LE is made of a conductive material, for example, Ru. The upper electrode UE is made of a conductive material, for example, W. In the same manner as in the First Embodiment, the variable resistance layer VR has a structure in which a transition metal oxide TMO is dispersed in a metal M. As has been detailed in the First Embodiment and so on, such an incorporation of the metal M into the transition metal oxide TMO makes it possible to restrain the memory element from undergoing OFF-fixation to improve the element in ON-properties. Also in the resistance random access memory elements RM in the present embodiment, an insulator film IF1 having openings OA is formed between the individual lower electrodes LE and the variable resistance layer VR. When the variable resistance region of each of the resistance random access memory elements RM is specified by the corresponding opening OA in this way to avoid any edge region of the corresponding section of the variable resistance layer VR, the edge portion being a portion damaged and further easily changed in Ru concentration at the time of the etching, the memory element can be decreased in dispersion of ON-properties and other element properties.

In the same manner as in the Fourth Embodiment, over the interconnection M1 and each of the upper electrodes UE, a plug and an interconnection are formed. In this example, specifically, a plug P2 is arranged over the interconnection M1 and the upper electrode UE, and an interconnection M2 is arranged over the plug P2.

As described herein, the semiconductor memory device of the present application example produces not only the advantageous effects as described in the Fourth Embodiment but also the following advantageous effects: The present application example makes the distance small between the interconnection M1 and the substrate S by locating the interconnection M1 over the interlayer dielectric IL1. This manner makes an improvement in the operation speed of semiconductor elements for a peripheral circuit for driving the memory cell array. Moreover, this application example is consistent in circuit operation speed with each semiconductor device (for example, a logic chip) in which no resistance random access memory element RM is formed; thus, the device (chip) can be heightened in circuit design interchangeability whether or not a resistance random access memory element is used therein.

[Description of Production Method]

The same manner as in the Fourth Embodiment is used in the step of forming plugs P1 and steps before the step. Specifically, transistors for selections are formed in the vicinity of a main surface of a substrate (p-type well PW) S made of a semiconductor, and further an interlayer dielectric IL1 is formed thereon. Thereafter, plugs P1 (coupling regions) are formed in the interlayer dielectric IL1.

Next, an interconnection M1 is formed on the plugs P1 in the interlayer dielectric IL1. The formation of the interconnection M1 is attained, using, for example, a damascene technique (a single damascene technique in this case). Specifically, an insulator film IL11 for making trenches is formed on the interlayer dielectric IL1, and then interconnection trenches are made in this trench-making insulator film IL11. Thereafter, a conductive film is embedded into the interconnection trenches to form an interconnection M1. The conductive film for forming the interconnection M1 may be a film made mainly of a metal such as W, Al or Cu.

Next, in the same manner as in the Fourth Embodiment, lower electrodes LE are formed on the interconnection M1. Next, an insulator film IF1 having openings OA is formed on the lower electrodes LE. Next, a variable resistance layer VR is formed on the openings OA. Specifically, for example, a Ta film is deposited onto the insulator film IF1 containing the openings OA; and next, the workpiece is subjected to plasma oxidizing treatment to oxidize the Ta film to form a Ta₂O₅ film, which has a chemically stoichiometric composition. Next, upper electrode UE layer (an oxygen withdrawing layer, an antioxidative layer and a main electrode layer) is formed, and the upper electrode UE layer and the variable resistance layer VR are patterned to form resistance random access memory elements RM.

Thereafter, in the same way as in the Fourth Embodiment, an insulator film (covering insulator film) IF2 and an interlayer dielectric IL2 are successively deposited onto the variable resistance layer VR. Plugs P2 are then formed in the interlayer dielectric IL2 and the insulator films IF1 and IF2. Next, a damascene technique is used to form an interconnection M2 on the interlayer dielectric IL2 in which the plugs P2 are embedded. In this example, the formation of the interconnection is according to the damascene method. However, the interconnections M1 and M2, and interconnections above the interconnection M1 may be formed by patterning.

### Application Example 2

In the Fourth Embodiment (FIG. 7), the openings OA have each been arranged just above substantially the center of the corresponding plug P1. However, the opening OA may be shifted from the upper surface of the plug P1.

[Description of Structure]

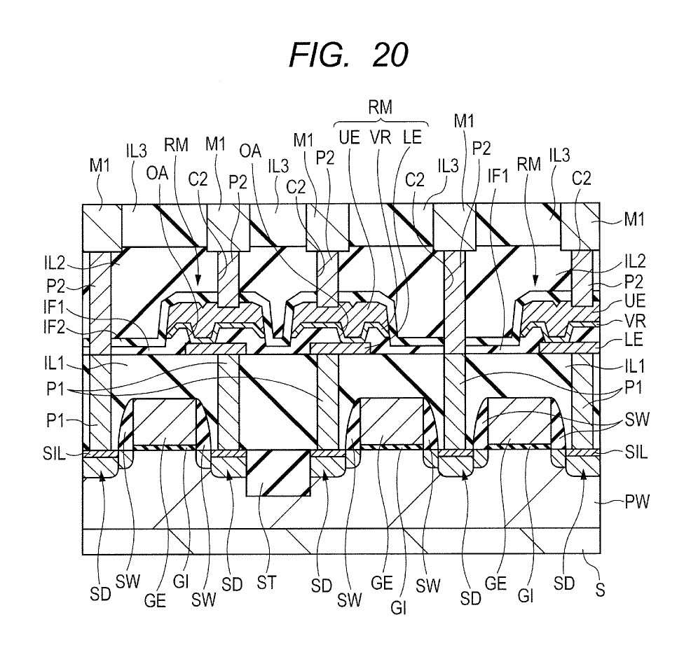

FIG. 20 is a sectional view of a structure of a semiconductor memory device of application example 2 of the present embodiment.

[Description of Production Method]

Transistors for selection each have the same structure as in the Fourth Embodiment. Specifically, each transistor for selection is located in a main surface of a substrate (p-type well PW) S and over a region divided by an element isolation region ST. The transistor has a gate electrode GE formed over the substrate S to interpose a gate insulator film GI therebetween, and source/drain regions SD located in the substrate (p-type well PW) S and at both sides of the gate electrode GE. The source/drain regions SD each have an LDD structure. Two plugs P1 are arranged, respectively, over the source-drain regions SD of the transistor for selection. One of the plugs P1 is coupled to a lower electrode LE of a resistance random access memory element RM. The other plug P1 is coupled to a plug P2. An interconnection M1 is embedded in a trench-making insulator film IL3.

Over each of the plugs P1, the corresponding resistance random access memory element RM is formed which has the lower electrode LE, a variable resistance layer VR and an upper electrode UE. The lower electrode LE is formed to be extended into one direction (direction toward the corresponding gate electrode GE in this example) from above the plug P1. This lower electrode LE is made of a conductive material, for example, Ru. An insulator film IF1 having openings OA is formed over the lower electrode LE. Each of the openings OA is arranged to be shifted from the corresponding plug P1. In the same way as in the Fourth Embodiment, over the opening OA, the variable resistance layer VR and the corresponding upper electrode UE are formed.

In the case of arranging, in this way, each of the openings OA for specifying a variable resistance region of the corresponding resistance random access memory element RM to be shifted from the corresponding plug P1, an effect onto the variable resistance region can be avoided, the effect being based on a step difference resulting from the plug P1. For example, if a seam (dent) or some other is made in the front surface of the plug P1, a dent corresponding to the seam is generated also in the front surface of the lower electrode LE on the plug P1. Thus, the flatness of the lower electrode LE is damaged. If the variable resistance layer VR and the corresponding upper electrode UE are successively formed over this low-flatness region, this resistance random access memory element is damaged in operation stability and evenness. However, as done in the present application example, each of the openings OA is arranged to be shifted for the corresponding plug P1 to prepare a variable resistance region, whereby the resistance random access memory elements can be improved in operation stability and evenness. Of course, when the variable resistance region of each of the resistance random access memory elements RM is specified by the corresponding opening OA in this way to avoid any edge region of the corresponding section of the variable resistance layer VR, the edge portion being a portion damaged and further easily changed in Ru concentration at the time of the etching, the memory element can be decreased in dispersion of ON-properties and other element properties.

The upper electrodes UE in the application example 2 are each made of a conductive material, for example, W. In the same manner as in the First Embodiment, the variable resistance layer VR has a structure in which a transition metal oxide TMO is dispersed in a metal M. As has been detailed in the First Embodiment and so on, such an incorporation of the metal M into the transition metal oxide TMO makes it possible to restrain the memory elements from undergoing OFF-fixation to improve the elements in ON-properties.

In the same manner as in the Fourth Embodiment, a plug P2 is arranged over each of the plugs P1 and the corresponding upper electrode UE. An interconnection M1 is arranged on the plug P2.

As described herein, the semiconductor memory device of the present application example produces not only the advantageous effects as described in the Fourth Embodiment but also the following advantageous effect: the present application example makes it possible to improve the resistance random access memory elements in operation stability and evenness by arranging the openings OA to be shifted from the plugs P1, respectively.

[Description of Production Method]

The same manner as in the Fourth Embodiment is used in the step of forming plugs P1 and steps before the step. Specifically, transistors for selections are formed in the vicinity of a main surface of a substrate (p-type well PW) S made of a semiconductor, and further an interlayer dielectric IL1 is formed thereon. Thereafter, plugs P1 (coupling regions) are formed in the interlayer dielectric IL1.

Next, lower electrodes LE are formed on the plugs P1 in the interlayer dielectric IL1. At this time, the lower electrodes LE are formed to be patterned and each extended into one direction (direction toward the corresponding gate electrode GE in this example) from above the corresponding plug P1. In other words, each of the plugs P1 is arranged on the one-end side of the corresponding lower electrode LE, and an opening-OA-made region, which will be specifically later, is located on the other-end side thereof. Next, an insulator film IF1 is formed on the lower electrodes LE, and a portion of the insulator film IF1 that is positioned on the other-end side of each of the lower electrodes LE. In this way, openings (referred to also as memory holes) OA are made. Next, a variable resistance layer VR is formed on the openings OA. Specifically, for example, a Ta film is deposited onto the insulator film IF1 containing the openings OA by sputtering. Next, the workpiece is subjected to plasma oxidizing treatment to oxide the Ta film, thereby forming a Ta₂O₅ film, which has a chemically stoichiometric composition. Next, an upper electrode UE layer (an oxygen withdrawing layer, an antioxidative layer and a main electrode layer) is formed, and the upper electrode UE layer and the variable resistance layer VR are patterned to form resistance random access memory elements RM.

Thereafter, in the same way as in the Fourth Embodiment, an insulator film (covering insulator film) IF2 and an interlayer dielectric IL2 are successively deposited onto the variable resistance layer VR. Plugs P2 are then formed in the interlayer dielectric IL2 and the insulator film IF2. Next, a damascene technique or some other is used to form an interconnection M1 on the interlayer dielectric IL2 in which the plugs P2 are embedded.

### Application Example 3

In the Second Embodiment (FIG. 20), two of the plugs P2 are arranged, respectively, over any adjacent two sections of the variable resistance layer VR. However, it is allowable to join the upper electrodes UE of any adjacent two of the resistance random access memory elements to each other to form a large-area upper electrode coupled to the two resistance random access memory elements, and then arrange the corresponding plug P2 onto this large-area upper electrode.

[Description of Structure]

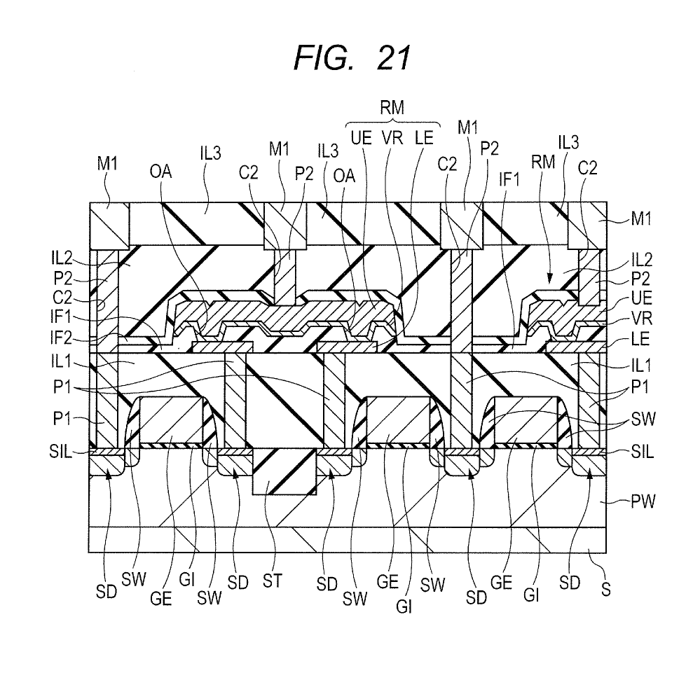

FIG. 21 is a sectional view of a structure of a semiconductor memory device of application example 3 of the present embodiment.

[Description of Production Method]

Transistors for selection each have the same structure as in the Fourth Embodiment. Specifically, each transistor for selection is located in a main surface of a substrate (p-type well PW) S and over a region divided by an element isolation region ST. The transistor has a gate electrode GE formed over the substrate to interpose a gate insulator film GI therebetween, and source/drain regions SD located in the substrate (p-type well PW) S and at both sides of the gate electrode GE. The source/drain regions SD each have an LDD structure. Two plugs P1 are arranged, respectively, over the source-drain regions SD of the transistor for selection. One of the plugs P1 is coupled to a lower electrode LE of a resistance random access memory element RM. The other plug P1 is coupled to a plug P2. An interconnection M1 is embedded in a trench-making insulator film IL11.

In FIG. 21, about each of two transistors for selection that are arranged symmetrically with each other to interpose an element isolation region ST, on an element-isolation-region-SD-side source/drain region thereof, a plug P1 is arranged. Over each of the two plugs P1, a resistance random access memory element RM is formed which has a lower electrode LE, a variable resistance layer VR section, and an upper electrode UE portion. The respective variable resistance layer VR sections of the two resistance random access memory elements (cells or unit cells), as well as the upper electrode UE portions thereof, are arranged to be joined with each other.

For example, one of the lower electrodes LE is arranged on each of the plugs P1 at both sides of the element isolation region ST. In the same manner as in application example 2, the lower electrode LE is formed to be extended into one direction (direction toward the corresponding gate electrode GE in this example) from above the plug P1. This lower electrode LE is made of a conductive material, for example, Ru.

An insulator film IF1 is formed on the two lower electrodes LE. Respective portions of the insulator film IF1 that are positioned on the lower electrodes LE are removed to make openings OA. In order to join the openings OA with each other, a laminated portion of the variable resistance layer VR and the upper electrode UE layer is arranged. On the upper electrode UE portions arranged oppositely to the two lower electrodes LE to interpose the variable resistance layer VR therebetween, one of the plugs P2 is arranged.

When the respective upper electrode UE portions of the two resistance random access memory elements are joined with each other in this way and thus the two resistance random access memory elements (cells or unit cells) have the upper electrode UE in common, the memory cell area can be made small in area. Moreover, the memory cell area can be made high in integration degree. In the present application example, the two resistance random access memory elements have the upper electrode UE in common. However, three or more resistance random access memory elements may have an upper electrode in common.

In the same manner as in application example 2, in the present application example, the openings OA are arranged to be shifted from the respective plugs P1. Thus, the resistance random access memory elements can be improved in operation stability and evenness.

The upper electrode UE is made of a conductive material, for example, W. In the same manner as in the First Embodiment, the variable resistance layer VR has a structure in which a metal M is dispersed in a transition metal oxide TMO. Such an incorporation of the metal M into the transition metal oxide TMO makes it possible to restrain each of the memory elements from undergoing OFF-fixation to improve the element in ON-properties. Also in the resistance random access memory element RM in the present embodiment, the insulator film IF1 having the openings OA is formed between the lower electrodes LE and the variable resistance layer VR. When the variable resistance region of the resistance random access memory element RM is specified by the corresponding opening OA in this way to avoid any edge region of the corresponding section of the variable resistance layer VR, the edge portion being a portion damaged and further easily changed in Ru concentration at the time of the etching, the memory element can be decreased in dispersion of ON-properties and other element properties.

Another plug P2 is arranged onto one of the plugs P1. In the same manner as in the Fourth Embodiment, an interconnection M1 is arranged on the plugs P1.

As described herein, the semiconductor memory device of the present application example produces not only the advantageous effects as described in application example 2 but also the following advantageous effect: the present application example makes it possible to make the resistance random access memory elements small in area by the matter that any pair of the resistance random access memory elements have the upper electrode UE in common. Moreover, the memory cell array can be heightened in integration degree.

[Description of Production Method]

The same manner as in the Fourth Embodiment is used in the step of forming plugs P1 and steps before the step. Specifically, transistors for selections are formed in the vicinity of a main surface of a substrate (p-type well PW) S made of a semiconductor, and further an interlayer dielectric IL1 is formed thereon. Thereafter, plugs P1 (coupling regions) are formed in the interlayer dielectric ILL

Next, in the same way as in application example 2, lower electrodes LE are formed on the plugs P1 in the interlayer dielectric ILL Specifically, lower electrodes LE are formed to be patterned and each extended into one direction (direction toward the corresponding gate electrode GE) from above the corresponding plug P1. In other words, the plug P1 is arranged on the one-end-side of the lower electrode LE, and an opening-OA-made region, which will be specifically later, is located on the other-end side of the lower electrode LE. Next, an insulator film IF1 is formed on the lower electrodes LE, and a portion of the insulator film IF1 that is positioned on the other-end side of each of the lower electrodes LE is removed. In this way, openings (referred to also as memory holes) OA are made.

Next, a variable resistance layer VR is formed on the openings OA. Specifically, for example, a Ta film is deposited onto the insulator film IF1 containing the openings OA by sputtering. Next, the workpiece is subjected to plasma oxidizing treatment to oxide the Ta film, thereby forming a Ta₂O₅ film, which has a chemically stoichiometric composition. Next, an upper electrode UE layer (an oxygen withdrawing layer, an antioxidative layer and a main electrode layer) is formed, and the upper electrode UE layer and the variable resistance layer VR are patterned. At this time, the upper electrode UE layer and the variable resistance layer VR are patterned to join paired two of the openings OA with each other.

Thereafter, in the same way as in the Fourth Embodiment, an insulator film (covering insulator film) IF2 and an interlayer dielectric IL2 are successively deposited onto the variable resistance layer VR. Plugs P2 are then formed in the interlayer dielectrics IL1 and IL2 and the insulator film IF2. At this time, it is sufficient for one of the plugs P2 to be formed on the upper electrode UE which the paired two (cells) of the resistance random access memory elements have in common. Next, a damascene technique or some other is used to form an interconnection M1 on the interlayer dielectric IL2 in which the plugs P2 are embedded.

The above has described the invention made by the inventors specifically by way of its embodiments. However, the present invention is not limited to the embodiments. Of course, the embodiments can be each variously modified as far as the modified embodiment does not depart from the subject matters of the invention.

For example, the interconnection structure between the plugs P1 and the plugs P2 in application example 1 may be applied to application example 2 or 3. A structure as described in application example 3, in which plural resistance random access memory elements (cells) have an upper electrode UE in common, may be applied to the Fourth Embodiment.

What is claimed is:

1. A semiconductor memory device, comprising:
a first electrode;
a second electrode; and
a variable resistance layer arranged between the first and second electrodes;
wherein the variable resistance layer comprises an oxide layer of a first metal, and a second metal contained in the oxide layer of the first metal,
wherein the first metal is a transition metal; and
wherein the second metal is a metal that produces an electronic level inside a band gap of the oxide layer of the first metal.

2. The semiconductor memory device according to claim 1,
wherein the oxide layer of the first metal comprises at least one selected from the group consisting of Ta₂O₅, ZrO₂, and HfO₂.

3. The semiconductor memory device according to claim 2,
wherein the second metal is selected from the group consisting of Ru, Re, Ir, Os, and Nb.

4. The semiconductor memory device according to claim 3,
wherein the content by percentage of the second metal is from 1 to 20% by atom of the first metal in the oxide layer of the first metal.

5. The semiconductor memory device according to claim 1,
wherein the variable resistance layer is over the first electrode, and
wherein the first electrode contains the second metal.

6. The semiconductor memory device according to claim 5,
wherein the second metal contained in the oxide layer of the first metal is a metal diffused from the first electrode.

7. The semiconductor memory device according to claim 1, which has a third metal layer between the second electrode and the variable resistance layer,
wherein the third metal layer contains at least one selected from the group consisting of Ta, Ti, Zr and Hf.

8. The semiconductor memory device according to claim 7, which has a compound layer of a fourth metal,
wherein the compound layer of the fourth metal has electroconductivity.

9. The semiconductor memory device according to claim 8,
wherein the compound layer of the fourth metal is selected from the group consisting of TaN, TiN, and WN.

10. The semiconductor memory device according to claim 1, which has a layer smaller in oxygen quantity proportion than the oxide layer of the first metal between the second electrode and the variable resistance layer.

11. The semiconductor memory device according to claim 10, which has a compound layer of a fourth metal between the second electrode, and the layer smaller in oxygen quantity proportion than the oxide layer of the first metal,
wherein the compound layer of the fourth metal has electroconductivity.

12. The semiconductor memory device according to claim 11,
wherein the compound layer of the fourth metal is selected from the group consisting of TaN, TiN, and WN.

13. The semiconductor memory device according to claim 5, which has an insulator film having an opening between the first electrode and the variable resistance layer.

14. A semiconductor memory device, comprising: a MISFET and a resistance random access memory element;
wherein the MISFET comprises a gate electrode arranged over a semiconductor substrate to interpose a gate insulator film therebetween, and source/drain regions formed at both sides of the gate electrode, respectively, and in the semiconductor substrate;
wherein the resistance random access memory element comprises a first electrode, a second electrode, and a variable resistance layer arranged between the first and second electrodes;
wherein the variable resistance layer comprises an oxide layer of a first metal, and a second metal contained in the oxide layer of the first metal;
wherein the first metal is a transition metal;
wherein the second metal is a metal that produces an electronic level inside a band gap of the oxide of the first metal, and
wherein the first electrode is electrically coupled to the source/drain regions.

15. A method for producing a semiconductor memory device, comprising the steps of:
(a) forming a first electrode over a semiconductor substrate;
(b) forming, over the first electrode, a variable resistance layer having an oxide layer of a first metal and a second metal contained in the oxide layer of the first metal; and
(c) forming a second electrode over the variable resistance layer;
wherein the first metal is a transition metal; and
wherein the second metal is a metal that produces an electronic level inside a band gap of the oxide layer of the first metal.

16. The method for producing a semiconductor memory device according to claim 15,
wherein the oxide layer of the first metal, which the variable resistance layer formed in the step (b) has, comprises at least one selected from the group consisting of Ta₂O₅, ZrO₂, and HfO₂.

17. The method for producing a semiconductor memory device according to claim 16,
wherein the second metal in the variable resistance layer formed in the step (b) is selected from the group consisting of Ru, Re, Ir, Os, and Nb.

18. The method for producing a semiconductor memory device according to claim 17,
wherein the content by percentage of the second metal is from 1 to 20% by atom of the first metal in the oxide layer of the first metal.

19. The method for producing a semiconductor memory device according to claim 18,
wherein the step (a) is a step of forming the first electrode containing the second metal;
wherein the step (b) comprises the steps:
(b1) depositing the first metal over the first electrode; and
(b2) oxidizing the first metal with plasma to form the oxide layer of the first metal, and diffusing the second metal in the first electrode into the oxide layer of the first metal.

20. The method for producing a semiconductor memory device according to claim 15, further comprising the following step (d) between the steps (b) and (c): the step (d) of forming, over the variable resistance layer, a third metal layer, or a layer smaller in oxygen quantity proportion than the oxide layer of the first metal.

21. The method for producing a semiconductor memory device according to claim 20, further comprising the following step (e) between the steps (d) and (c): the step (e) of forming a compound layer of a fourth metal over the third metal layer or the layer smaller in oxygen quantity proportion than the oxide layer of the first metal.

22. The method for producing a semiconductor memory device according to claim 15, comprising a step (f) between the steps (a) and (b), the step (f) comprising the steps of:
(f1) forming an insulator film over the first electrode; and
(f2) making, in the insulator film, an opening for making the first electrode naked; and
the step (b) of forming the variable resistance layer over the first electrode and the opening.

23. The method for producing a semiconductor memory device according to claim 15, comprising, before the step (a), the step (g) of forming a MISFET over the semiconductor substrate,
the first electrode in the step (a) being formed to be electrically coupled to source/drain regions of the MISFET.
